(19) United States
(12) Patent Application Publication
(10) Pub. No.: US 2015/0114835 A1
(43) Pub. Date: Apr. 30, 2015

(54) FILM FORMING APPARATUS

(71) Applicant: Tokyo Electron Limited, Tokyo (JP)

(72) Inventors: Atsushi GOMI, Yamanashi (JP); Shinji FURUKAWA, Yamanashi (JP); Kanto NAKAMURA, Yamanashi (JP); Kazunaga ONO, Yamanashi (JP)

(21) Appl. No.: 14/525,096

(22) Filed: Oct. 27, 2014

(30) Foreign Application Priority Data
Oct. 31, 2013 (JP) 2013-226336

(51) Int. Cl. H01J 37/34

(52) U.S. Cl. CPC H01J 37/3408; H01J 37/3423; H01J 37/3455; H01J 37/3452
USPC 204/298.08

(57) ABSTRACT

A film forming apparatus includes a stage provided in the processing chamber; three or more targets uniformly arranged along a circle centering around a vertical axis line that passes through a center of the stage, each of the targets having a substantially rectangular shape; a shutter provided between the targets and the stage, the shutter including an opening which allows one of the targets to be selectively exposed to the stage; and a rotation shaft coupled to the shutter, the rotation shaft extending along the vertical axis line. A width of the opening in a tangent direction to the circle centering around the vertical axis line is set such that two adjacent targets in a circumferential direction of the circle among the targets are allowed to be partially and simultaneously exposed to the stage.

### CROSS-REFERENCE TO RELATED APPLICATIONS

This application claims priority to Japanese Patent Application No. 2013-226336 filed on Oct. 31, 2013, the entire contents of which are incorporated herein by reference.

### FIELD OF THE INVENTION

The present invention relates to a film forming apparatus; and, more particularly, to a film forming apparatus for forming a film on an object to be processed by sputtering.

### BACKGROUND OF THE INVENTION

When electronic devices are manufactured, various treatments are performed on an object. Film formation is an example of the treatments performed on the object. Further, sputtering may be used for the film formation.

A film forming apparatus for use in sputtering may include a processing chamber, a stage, a plurality of targets, a plurality of shutters, and a plurality of rotation shafts. In such a film forming apparatus, the stage is provided in the processing chamber, and the targets are disposed in a circumferential direction above the stage. Further, the shutters are each disposed between the stage and each of the targets and respectively coupled to the rotation shafts. In such a film forming apparatus, one or more targets selected among the targets are exposed to the stage by rotating the shutters. Therefore, the film forming apparatus can deposit substances sputtered from the one or more targets onto the object. Such a film forming apparatus is disclosed in Japanese Patent Application Publication Nos. 2005-256112, 2007-131883, 2009-221595 and 2002-506490.

As described above, in a general film forming apparatus, a plurality of rotation shafts is required to rotate a plurality of shutters. Further, a plurality of driving units is required to rotate the rotation shafts. Therefore, the cost of the film forming apparatus is increased and the control required to set rotation positions of the shutters becomes complicated.

### SUMMARY OF THE INVENTION

In view of the above, the present invention provides a cost-effective film forming apparatus capable of easily exposing one or two targets selected among a plurality of targets to a stage.

In accordance with an aspect of the present invention, there is provided a film forming apparatus including: a processing chamber; a stage provided in the processing chamber; three or more targets uniformly arranged along a circle centering around a vertical axis line that passes through a center of the stage in a vertical direction, each of the targets having a substantially rectangular shape; a gas supply unit configured to supply a gas into the processing chamber; a power supply configured to generate a negative DC voltage to be applied to the targets; a shutter provided between the targets and the stage, the shutter including an opening which allows one of the targets to be selectively exposed to the stage; and a rotation shaft coupled to the shutter, the rotation shaft extending along the vertical axis line, wherein a width of the opening in a tangent direction to the circle centering around the vertical axis line is set such that two adjacent targets in a circumferential direction of the circle among the targets are allowed to be partially and simultaneously exposed to the stage.

As described above, there is provided a cost-effective film forming apparatus capable of easily exposing one or two targets selected among a plurality of targets to a stage.

### BRIEF DESCRIPTION OF THE DRAWINGS

The objects and features of the present invention will become apparent from the following description of embodiments, given in conjunction with the accompanying drawings, in which:

FIG. 1 schematically shows a film forming apparatus in accordance with an embodiment of the present invention;

FIG. 2 is a top view showing a top surface of a shutter, on which targets are projected in a normal direction of each point on the top surface of the shutter;

FIG. 3 is a top view showing a top surface of a shutter, on which the targets are projected in the normal direction of each point on the top surface of the shutter;

FIG. 4 is a top view showing a top surface of a shutter, on which the targets and cathode magnets are projected in the normal direction of each point on the top surface of the shutter; and

FIG. 5 is a top view showing a top surface of a shutter, on which the targets and the cathode magnets are projected in the normal direction of each point on the top surface of the shutter.

### DETAILED DESCRIPTION OF THE EMBODIMENTS

Hereinafter, embodiments of the present invention will be described with reference to the accompanying drawings which form a part hereof. Further, like reference numerals will be used for like or corresponding parts in the respective drawings.

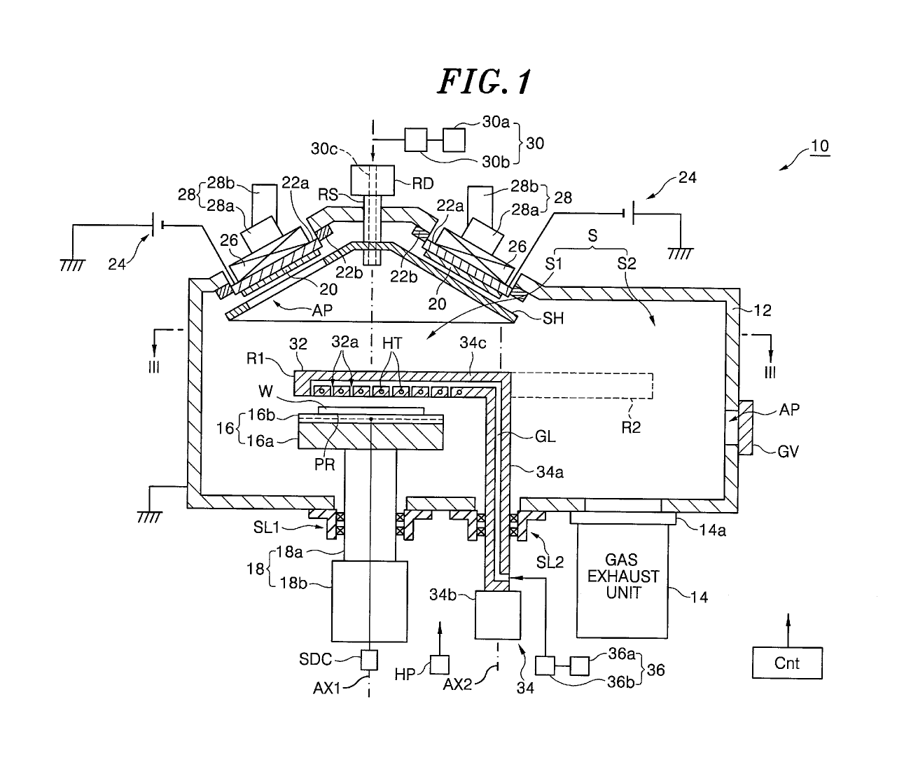

FIG. 1 schematically shows a vertical cross section of a film forming apparatus in accordance with an embodiment of the present invention. A film forming apparatus 10 shown in FIG. 1 includes a processing chamber 12. The processing chamber 12 is made of, e.g., aluminum, and connected to a ground potential. The processing chamber 12 has a space S therein. A gas exhaust unit 14 for decreasing a pressure in the space S is connected to a bottom wall of the processing chamber 12 through an adaptor 14a. Further, an opening AP, through which an object to be processed (hereinafter, referred to as “wafer”) is transferred, is formed at a sidewall of the processing chamber 12, and a gate valve GV for opening/closing the opening AP is also provided at the sidewall.

A stage 16 is provided in the processing chamber 12. The stage 16 includes a base 16a and an electrostatic chuck 16b. The base 16a is made of, e.g., aluminum, and formed in a substantially disc shape. In the present embodiment, the base 16a may have therein a temperature control mechanism. For example, the base 16a may have therein a coolant path for circulating a coolant.

The electrostatic chuck 16b is provided above the base 16a. The electrostatic chuck 16b includes a dielectric film and an electrode embedded in the dielectric film. A DC power supply SDC is connected to the electrode of the electrostatic chuck 16b. The wafer W mounted on the electrostatic chuck 16b is attracted and held on the electrostatic chuck 16b by electrostatic force generated by the electrostatic chuck 16b. Further, a region on the top surface of the electrostatic chuck 16b where the wafer W is mounted is referred to as a mounting region PR for the wafer W.

The stage 16 is connected to a stage driving unit 18. The stage driving unit 18 includes a supporting shaft 18a and a driving device 18b. The supporting shaft 18a has a substantially columnar shape. A central axis line of the supporting shaft 18a substantially coincides with a vertical axis line AX1 that passes through the center of the mounting region PR, i.e., the center of the stage 16 in the vertical direction. The supporting shaft 18a extends downwardly from the stage 16 to the outside of the processing chamber 12, penetrating through the bottom wall of the processing chamber 12. A seal member SL1 is provided between the supporting shaft 18a and the bottom wall of the processing chamber 12. The seal member SL1 seals the space between the bottom wall of the processing chamber 12 and the supporting shaft 18a such that the supporting shaft 18a can rotate and vertically move. The seal member SL1 may be, e.g., a magnetic fluid seal.

The stage 16 is connected to an upper end of the supporting shaft 18a, and the driving device 18b is connected to a lower end of the supporting shaft 18a. The driving device 18b generates power for rotating and vertically moving the supporting shaft 18a. By the power of the driving device 18b, the supporting shaft 18a is rotated to rotate the stage 16 about the axis line AX1, and is vertically moved to vertically move the stage 16.

A plurality of, e.g., three or more, targets (cathode targets) 20 is provided above the stage 16. In the present embodiment, four targets 20a, 20b, 20c and 20d are provided in the film forming apparatus 10. Hereinafter, the film forming apparatus 10 including four targets will be described as an example. However, the number of targets is not limited as long as it is greater than or equal to 3.

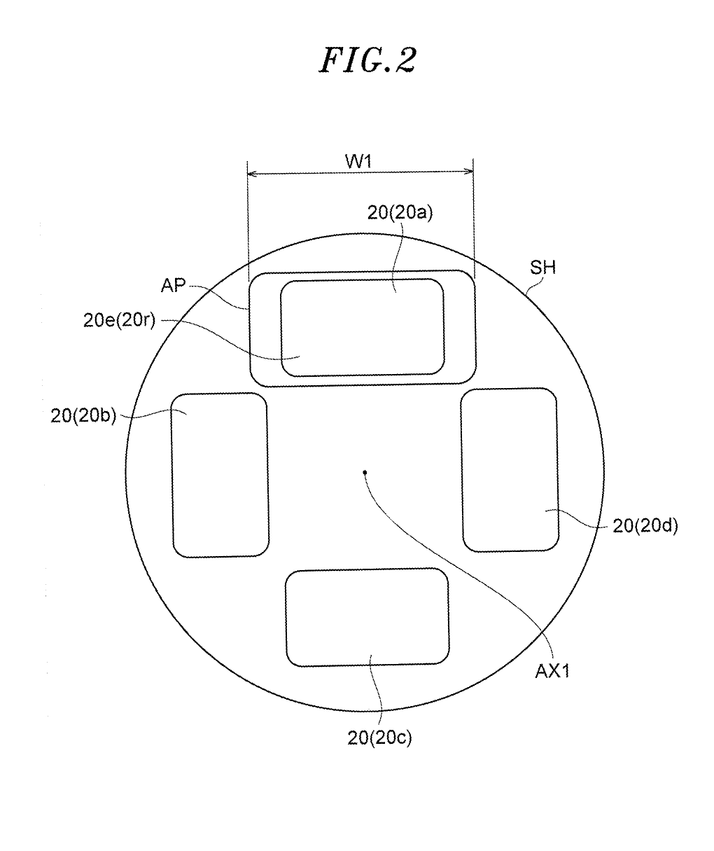

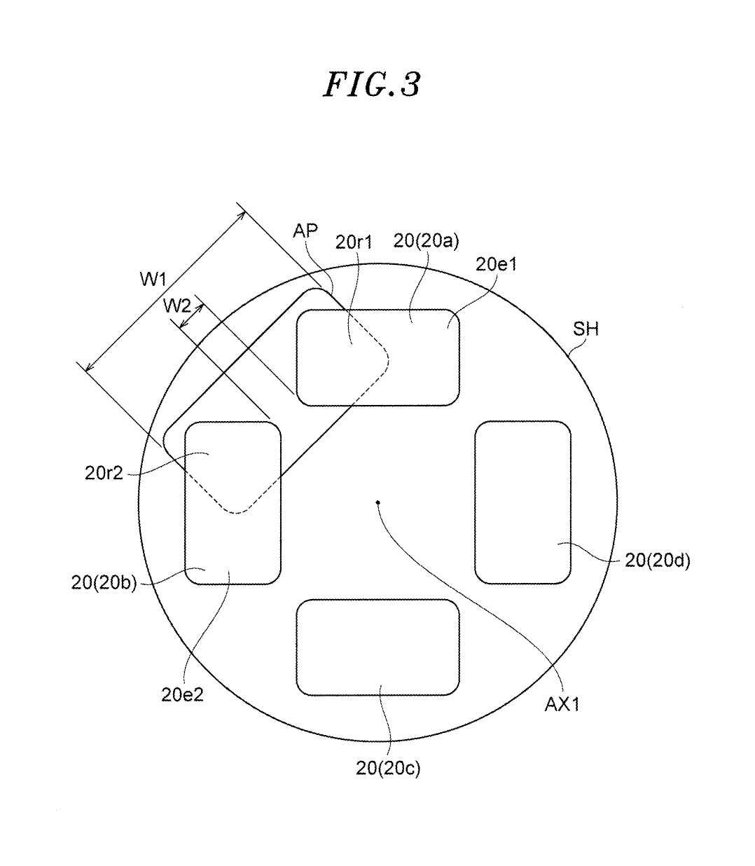

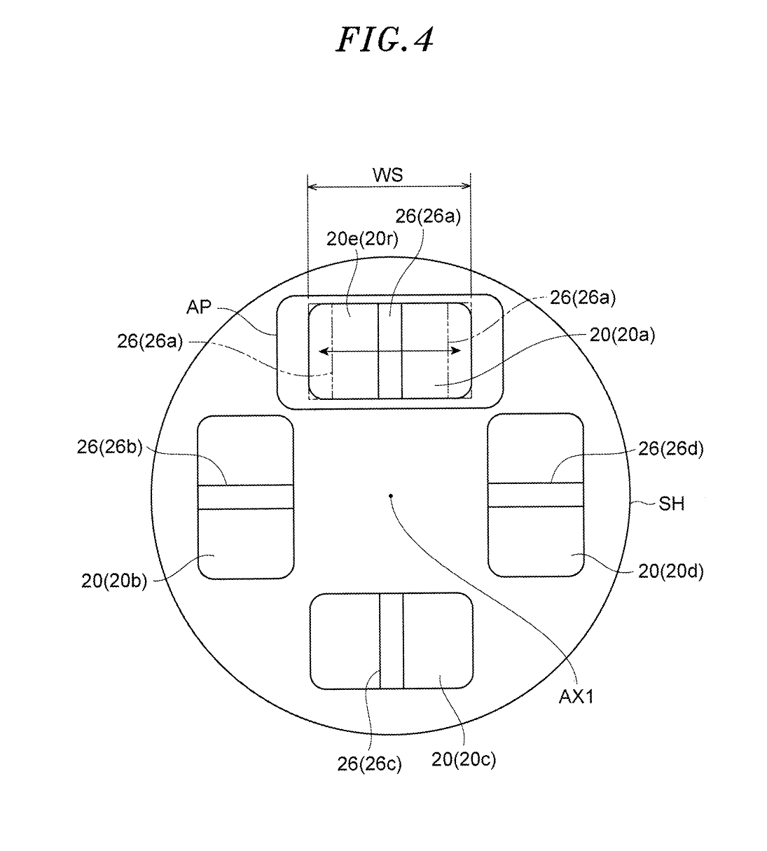

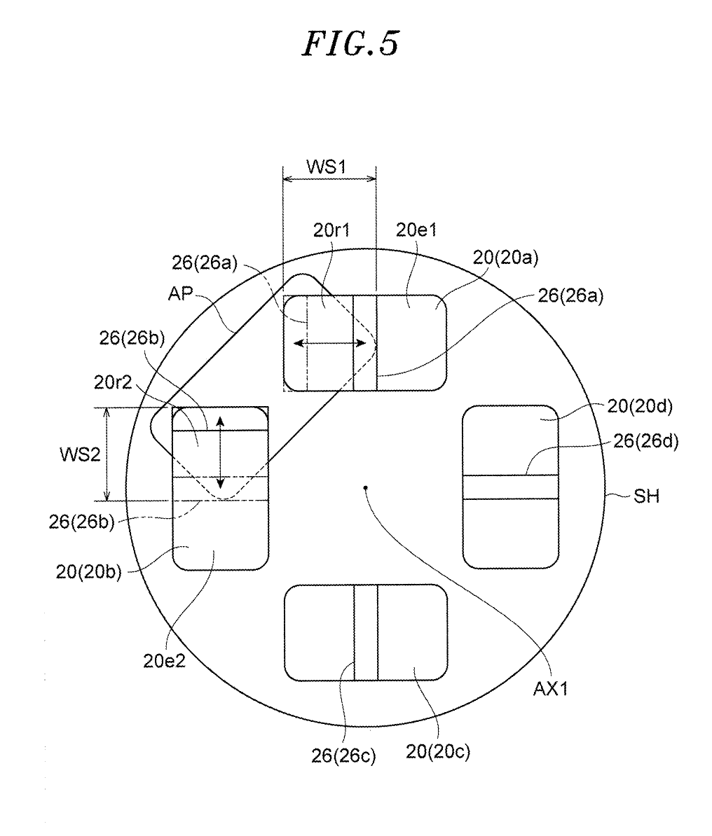

In the film forming apparatus 10, a shutter SH is provided between the targets 20 and the stage 16. Further, in the film forming apparatus 10, a plurality of magnets (cathode magnets) 26 is provided outside the processing chamber 12 so as to respectively face the corresponding targets 20 through holders 22a. FIGS. 2 and 3 are top views showing the top surface of the shutter on which the targets are projected in a normal direction of each point on the top surface of the shutter. FIGS. 4 and 5 are top views showing the top surface of the shutter on which the targets and the cathode magnets are projected in the normal direction of each point on the top surface of the shutter. FIGS. 2 and 4 show a state in which a single target faces an opening of the shutter. FIGS. 3 and 5 show a state in which two targets face the opening of the shutter. Hereinafter, FIGS. 2 to 5 will be also referred to in addition to FIG. 1.

Each of the targets 20 has a substantially rectangular plate shape. In other words, each of the targets 20 has four edges along four sides of the rectangle. For example, as shown in FIG. 2, each of the targets 20 has a substantially rectangular shape that is long in a tangent direction to a circle centering around the axis line AX1. The targets 20 are substantially uniformly arranged along the circle centering around the axis line AX1. In other words, the targets 20 are spaced apart from each other at a substantially uniform interval in a circumferential direction about the axis line AX1. Further, the targets 20 are inclined with respect to the axis line AX1 so as to face the stage 16.

The materials of the targets 20 are selected depending on the types of films that are desired to be formed. In the present embodiment, the targets 20 are made of different kinds of metals. For example, two targets adjacent to each other in a circumferential direction may be made of cobalt and platinum, respectively. Otherwise, two targets adjacent to each other in the circumferential direction may be made of nickel and iron, respectively. One of the targets 20 may be made of magnesium.

Each of the targets 20 is held by a metallic holder 22a. The holder 22a is supported by a ceiling portion of the processing chamber 12 through an insulating member 22b. A power supply 24 is connected to each of the targets 20 through the holder 22a. The power supply 24 applies a negative DC voltage to each of the targets 20. The power supply 24 may be a single power supply for selectively applying a voltage to the targets 20 or may be a combination of multiple power supplies respectively connected to the targets 20.

The shutter SH is provided between the targets 20 and the stage 16. The shutter SH extends so as to correspond to surfaces of the targets 20. In the present embodiment, the shutter SH has a shape extending along a circular conical surface having the axis line AX1 as the central axis line.

The opening AP is formed in the shutter SH. As shown in FIG. 2, one of the targets 20 can be selectively exposed to the stage 16 through the opening AP. Alternatively, as shown in FIG. 3, two of the targets 20 can be partially and simultaneously exposed to the stage 16 through the opening AP. Hereinafter, one or two targets exposed to the stage 16 through the opening AP among the targets 20 are referred to as “exposed targets”. Moreover, among the entire region of the exposed targets, a region that is actually exposed to the stage 16 through the opening AP, i.e., an unshielded region, is referred to as “exposed region”.

As shown in FIGS. 2 and 3, the opening AP has a width W1 in a tangent direction to a circle centering around the axis line AX1. For example, the opening AP has a planar size greater than that of each of the targets 20. In other words, the opening AP has a size that allows an entire region of one exposed target 20e (target 20a in FIG. 2) selected among the targets 20 to be exposed to the stage 16. In this case, the width W1 is greater than a width in a tangent direction of each of the targets 20. Further, as shown in FIG. 3, the width W1 of the opening AP is greater than a minimum distance W2 between two adjacent targets in the circumferential direction.

The shutter SH can expose one target 20e selected among the targets 20 to the stage 16 and shield the other targets. When the exposed target 20e is only one, an exposed region 20r becomes the entire region of the exposed target 20e, as shown in FIG. 2. Alternatively, as shown in FIG. 3, the shutter SH can expose parts of two exposed targets 20e1 and 20e2 adjacent to each other in the circumferential direction among the targets 20 to the stage 16 and shield the other parts of the exposed targets 20e1 and 20e2 and the other targets. For example, when the targets 20a and 20b are the exposed targets 20e1 and 20e2, a part of the target 20a close to the target 20b becomes an exposed region 20r1 and a part of the target 20b close to the target 20a becomes an exposed region 20r2.

As shown in FIG. 1, a rotation shaft RS is coupled to the central portion of the shutter SH. The rotation shaft RS has a substantially columnar shape, and a central axis line thereof substantially coincides with the axis line AX1. One end of the rotation shaft RS is coupled to the central portion of the shutter SH in the processing chamber 12. Further, the rotation shaft RS extends from the inside of the processing chamber 12 to the outside of the processing chamber 12, penetrating through the ceiling of the processing chamber 12. The other end of the rotation shaft RS is connected to a rotation driving unit RD at the outside of the processing chamber 12. The rotation driving unit RD generates power for rotating the rotation shaft RS. The rotation shaft RS is rotated about the axis line AX1 by the power thus generated, so that the shutter SH can rotate about the axis line AX1. The position of the opening AP in the circumferential direction can be adjusted by the rotation of the shutter SH.

As shown in FIG. 1, the cathode magnets 26 are provided outside the processing chamber 12 so as to face the targets 20 corresponding thereto. In the present embodiment, the film forming apparatus 10 includes magnets 26a, 26b, 26c and 26d as the cathode magnets 26. The magnets 26a to 26d face the targets 20a to 20d, respectively.

As shown in FIG. 1, the film forming apparatus 10 further includes a plurality of scanning units 28 for respectively scanning the magnets 26. Each of the scanning units 28 scans a corresponding magnet among the magnets 26 in a tangent direction to the circle centering around the vertical axis line AX1.

In the present embodiment, each of the scanning units 28 includes a guide portion 28a and a driving device 28b. The guide portion 28a is a guide member such as a rail or the like which extends in the tangent direction. The driving device 28b generates power for moving the magnet 26 along the guide portion 28a. The scanning unit 28 scans the magnet 26 corresponding to the exposed target within a scanning range corresponding to the opening AP. In other words, the magnet 26 is scanned within the scanning range corresponding to the width of the exposed region. Therefore, in the film forming apparatus 10, the high plasma density region can be restricted to the vicinity of the exposed region. As a result, the sputtering of targets in a region that is not exposed through the opening AP can be suppressed.

The film forming apparatus 10 further includes a gas supply unit 30 for supplying a gas into the processing chamber 12. In the present embodiment, the gas supply unit 30 includes a gas source 30a, a flow rate controller 30b such as a mass flow controller or the like, and a gas inlet 30c. The gas source 30a is a source of a gas that is to be excited in the processing chamber 12, e.g., Ar gas. The gas source 30a is connected to the gas inlet 30c via the flow rate controller 30b. The gas inlet 30c is a gas line through which a gas from the gas source 30a is introduced into the processing chamber 12. In the present embodiment, the gas inlet 30c extends along the axis line AX1.

When the gas is supplied into the processing chamber 12 from the gas supply unit 30 and a voltage is applied to the exposed target by the power supply 24, the gas supplied into the processing chamber 12 is excited. Further, when the scanning unit 28 scans the magnet 26 corresponding thereto, a magnetic field is generated near the exposed region of the exposed target. Accordingly, a plasma is concentrated near the exposed region. Then, positive ions in the plasma collide with the exposed region of the exposed target to thereby substances of the exposed target are sputtered from the exposed target and deposited on the wafer W.

In the present embodiment, the film forming apparatus 10 may further include a head 32, as shown in FIG. 1. The head 32 is configured to inject an oxidizing gas for oxidizing the metal deposited on the wafer W toward the stage 16.

The head 32 is connected to a head driving unit 34, which axially supports the head 32. In the present embodiment, the head driving unit 34 includes a supporting shaft 34a and a driving device 34b. The supporting shaft 34a has a substantially columnar shape, and a central axis line thereof substantially coincides with an axis line AX2. The axis line AX2 is substantially parallel to the axis line AX1 and extends in a vertical direction at the side of the stage 16. In the present embodiment, the head 32 has a substantially disc shape. A distance between the center of the head 32 and the axis line AX2 is substantially equal to a distance between the axis lines AX1 and AX2.

The supporting shaft 34a extends from the inside of the processing chamber 12 to the outside of the processing chamber 12. A seal member SL2 is provided between the supporting shaft 34a and the bottom wall of the processing chamber 12. The seal member SL2 seals the space between the bottom wall of the processing chamber 12 and the supporting shaft 34a such that the supporting shaft 34a can be rotated. The seal member SL2 is, e.g., a magnetic fluid seal.

An upper end of the supporting shaft 34a is connected to one end of a connection portion 34c. The connection portion 34c extends in a direction perpendicular to the axis line AX2. The other end of the connection portion 34c is coupled to a peripheral portion of the head 32. A lower end of the supporting shaft 34a is connected to the driving device 34b. The driving device 34b generates power for rotating the supporting shaft 34a. The head 32 pivots about the axis line AX2 by the rotation of the supporting shaft 34a.

Specifically, the head 32 moves between a first region R1 and a second region R2 by the operation of the driving unit 34. The first region R1 refers to a region above the stage 16 and within a space S1 between the targets 20 and the stage 16. The second region R2 refers to a region within a space S2 separated from the space S1.

An oxidizing gas line GL is formed in the supporting shaft 34a, the connection portion 34c, and the head 32. One end of the gas line GL is placed outside the processing chamber 12, and is connected to a gas supply unit 36. The gas supply unit 36 includes a gas source 36a, and a flow rate controller 36b such as a mass flow controller or the like. The gas source 36a is a source of an oxidizing gas, e.g., O₂ gas. The gas source 36a is connected to the one end of the gas line GL via the flow rate controller 36b.

The gas line GL in the head 32 is connected to a plurality of gas injection holes 32a formed in the head 32. In the present embodiment, the gas injection holes 32a may be distributed over a substantially entire region of the disc-shaped head 32. Further, the gas injection holes 32a may be arranged in a direction perpendicular to the axis line AX2. In the present embodiment, the head 32 has a planar size greater than the mounting region PR of the stage 16. In other words, the head 32 has a size that can cover the wafer W, between the stage 16 and the targets 20. Moreover, the head 32 may have an elongated planar shape extending in the arrangement direction of the gas injection holes 32a.

In the present embodiment, the head 32 includes a heater HT, as shown in FIG. 1. The heater HT may use any one of various types of heating method such as lamp emission, Joule resistance heating, induction heating, microwave heating and the like. A heater power supply HP is connected to the heater HT. The heater HT generates heat by power from the heater power supply HP.

In accordance with the film forming apparatus 10 configured as described above, depositing metal on the wafer W and oxidizing the metal can be performed in the same processing chamber 12. Specifically, the metal can be deposited by sputtering the metal from the target 20 in a state where the head 32 is positioned at the second region R2. Further, the deposited metal can be oxidized by supplying an oxidizing gas toward the wafer W in a state where the head 32 is positioned at the first region R1. As such, in accordance with the film forming apparatus 10, depositing metal on the wafer W and oxidizing the metal can be performed in the same processing chamber 12, so that it is possible to shorten time required to form a metal oxide film. Further, the target used for formation of the metal oxide film is made of, e.g., magnesium.

In addition, the film forming apparatus 10 may heat the oxidizing gas by using the heater HT during the oxidation of the metal. Accordingly, the oxidation of the metal can be facilitated, and the time required for the oxidation of the metal can be further shortened.

In accordance with the film forming apparatus 10, before the metal is deposited, a process of sputtering the surface of the target 20, i.e., a pre-sputtering process, can be performed in a state where the wafer W is covered with the head 32 located at the first region R1. Therefore, in accordance with the film forming apparatus 10, the contamination of the wafer W during the pre-sputtering can be reduced or prevented.

In the present embodiment, the film forming apparatus 10 may include a controller Cnt as shown in FIG. 1. The controller Cnt controls the components of the film forming apparatus 10. The controller Cnt is, e.g., a computer device, and may include an input device such as a keyboard, a touch panel or the like, a storage unit such as a memory for storing a recipe or the like, a central processing unit CPU, and an output interface for outputting control signals to the components of the film forming apparatus 10.

Specifically, the controller Cnt controls the rotation position of the shutter SH by transmitting the control signal to the rotation driving unit RD. Thus, one or two targets among the targets 20 can be exposed to the stage 16 through the opening AP.

Further, the controller Cnt transmits the control signal to the flow rate controller 30b of the gas supply unit 30 to supply a gas at a predetermined flow rate from the gas supply unit 30 into the processing chamber 12. The controller Cnt also transmits the control signal to the gas exhaust unit 14 to set a pressure in the processing chamber to a predetermined level. The controller Cnt also transmits the control signal to the driving device 34b to set the position of the head 32. For example, in the case of depositing the metal sputtered from the exposed target on the wafer W, the controller Cnt allows the head 32 to be positioned at the second region R2. In the case of oxidizing the metal deposited on the wafer W, the controller Cnt allows the head 32 to be positioned at the first region R1. The controller Cnt also transmits the control signal to the heater power supply HP. As a consequence, the head 32 can be heated, and the oxidizing gas flowing through the head 32 can be heated.

The controller Cnt also transmits the control signal to the power supply 24 to apply a negative DC voltage to the exposed target. The controller Cnt also transmits the control signal to the driving device 28b of the scanning unit 28. By the control signal, the corresponding magnet 26 can be scanned within a scanning range corresponding to the width of the exposed region of the exposed target.

For example, as shown in FIG. 4, when the target 20a is selected as the single exposed target 20e, the magnet 26a can reciprocally move within a scanning range that is substantially the same as a width WS of the exposed region 20r in the scanning direction of the magnet 26a. Further, the scanning of the other magnets can be stopped.

As shown in FIG. 5, when the targets 20a and 20b are selected as two exposed targets 20e1 and 20e2, the magnet 26a can reciprocally move within a scanning range that is substantially the same as a width WS1 of the exposed region 20r1 of the target 20a in the scanning direction of the magnet 26a. Moreover, the magnet 26b can reciprocally move within a scanning range that is substantially the same as a width WS2 of the exposed region 20r2 of the target 20b in the scanning direction of the magnet 26b. Further, the scanning of the other magnets can be stopped.

The film forming apparatus 10 described above can perform film formation using a material sputtered from a single target selected among the targets 20 or different materials sputtered from two adjacent targets selected among the targets 20. Further, the film forming apparatus 10 includes a single shutter SH as a shielding body for selectively exposing one or two targets selected among the targets 20 to the stage 16. The film forming apparatus 10 includes a single rotation shaft RS as a rotation shaft for rotating the shutter and also includes a single rotation driving unit RD as a driving unit for rotating the rotation shaft RS. Therefore, the cost of the film forming apparatus 10 can be reduced. In accordance with the film forming apparatus 10, the shutter SH can be relatively simply controlled.

While the invention has been shown and described with respect to the embodiments, it will be understood by those skilled in the art that various changes and modifications may be made without departing from the scope of the invention as defined in the following claims.

What is claimed is:

1. A film forming apparatus comprising:
a processing chamber;
a stage provided in the processing chamber;
three or more targets uniformly arranged along a circle centering around a vertical axis line that passes through a center of the stage in a vertical direction, each of the targets having a substantially rectangular shape;
a gas supply unit configured to supply a gas into the processing chamber;
a power supply configured to generate a negative DC voltage to be applied to the targets;
a shutter provided between the targets and the stage, the shutter including an opening which allows one of the targets to be selectively exposed to the stage; and
a rotation shaft coupled to the shutter, the rotation shaft extending along the vertical axis line,
wherein a width of the opening in a tangent direction to the circle centering around the vertical axis line is set such that two adjacent targets in a circumferential direction of the circle among the targets are allowed to be partially and simultaneously exposed to the stage.

2. The film forming apparatus of claim 1, wherein the width of the opening is greater than a minimum distance between two adjacent targets in the circumferential direction among the targets.

3. The film forming apparatus of claim 1, wherein the shutter serves as a shield member for selectively exposing one target or two adjacent targets in the circumferential direction among the targets to the stage.

4. The film forming apparatus of claim 2, wherein the shutter serves as a shield member for selectively exposing one target or two adjacent targets in the circumferential direction among the targets to the stage.

5. The film forming apparatus of claim 1, further comprising:
a plurality of magnets provided outside the processing chamber so as to respectively face the targets corresponding thereto;
a plurality of scanning units configured to scan the magnets in the tangent direction to the circle centering around the vertical axis line; and
a controller configured to control the scanning units to scan the magnets within a scanning range which corresponds to the opening.

6. The film forming apparatus of claim 2, further comprising:
a plurality of magnets provided outside the processing chamber so as to respectively face the targets corresponding thereto;
a plurality of scanning units configured to scan the magnets in the tangent direction to the circle centering around the vertical axis line; and
a controller configured to control the scanning units to scan the magnets within a scanning range which corresponds to the opening.

7. The film forming apparatus of claim 3, further comprising:
a plurality of magnets provided outside the processing chamber so as to respectively face the targets corresponding thereto;
a plurality of scanning units configured to scan the magnets in the tangent direction to the circle centering around the vertical axis line; and
a controller configured to control the scanning units to scan the magnets within a scanning range which corresponds to the opening.

8. The film forming apparatus of claim 4, further comprising:
a plurality of magnets provided outside the processing chamber so as to respectively face the targets corresponding thereto;
a plurality of scanning units configured to scan the magnets in the tangent direction to the circle centering around the vertical axis line; and
a controller configured to control the scanning units to scan the magnets within a scanning range which corresponds to the opening.
